(19) United States
(12) Patent Application Publication
(10) Pub. No.: US 2005/0118839 A1
(43) Pub. Date: Jun. 2, 2005

(54) Chemical mechanical polish process control method using thermal imaging of polishing pad

(75) Inventor: Lai-Juh Chen, Hsinchu (TW)

Correspondence Address: George O. Saile, 28 Davis Avenue, Poughkeepsie, NY, 12603, US

(73) Assignee: Industrial Technology Research Institute

(21) Appl. No.: 10/812,735

(22) Filed: Mar. 30, 2004

Related U.S. Application Data
(63) Continuation of application No. 09/298,450, filed on Apr. 23, 1999, now abandoned.

(51) Int. Cl. H01L 21/324

(52) U.S. Cl. 438/795

(57) ABSTRACT

A method and apparatus for controlling CMP (Chemical Mechanical Polishing) for semiconductor substrates includes an infrared camera for detecting and mapping in two dimensions the thermal image of the polishing pad during CMP. The thermal image of the polishing pad is then analyzed and used to control the process parameters of the CMP process. Analysis of the thermal image of the polishing pad allows real time endpoint detection of the CMP process and, also, real time adjustment of process parameters to improve the uniformity of removal of material across the semiconductor substrate.

### BACKGROUND OF THE INVENTION

(1) Field of the Invention

This invention relates to a method and apparatus for controlling a CMP (Chemical Mechanical Polishing) process in real time by measuring and mapping in two dimensions the surface temperature of the polishing pad during the CMP process. Additionally, the invention is directed to a method of determining the uniformity of removal of material from a semiconductor substrate during chemical mechanical polishing of the semiconductor substrate.

(2) Description of Related Art

In the fabrication of semiconductor integrated circuits CMP (Chemical Mechanical Polishing) can be used to remove different layers of material from the surface of a semi-conductor substrate. For example, following contact hole formation in an insulating layer, a metallization layer is deposited and then CMP is used to produce planar metal plugs embedded in the insulating layer. Similarly, interconnection wiring can be formed by first etching wiring channels into an insulating layer and then depositing a metallization layer onto the insulating layer and into the etched channels. CMP is then used to selectively remove the metallization layer from the surface of the insulating layer, leaving the metallization material embedded in the etched channels. Also, CMP has been developed for providing smooth topographies on insulating layers deposited on semiconductor substrates. It is desirable that insulating layers have smooth topography because it is difficult to lithographically image and pattern layers applied to rough surfaces.

Briefly, the CMP processes involve holding and rotating a thin, flat substrate of the semiconductor material against a rotating polishing surface under controlled chemical, pressure and temperature conditions. A chemical slurry containing a polishing agent, such as alumina or silica, is used as the abrasive material applied between the rotating semiconductor substrate and the rotating polishing surface. Additionally, the chemical slurry contains selected chemicals which etch various surfaces of the substrate during processing. The combination of mechanical and chemical removal of material during polishing results in superior planarization of the polished surface.

An important challenge in CMP is to determine the process endpoint in real time without a necessity for interrupting the CMP process, removing the substrate from the polishing apparatus, and physically examining the substrate surface by techniques which ascertain film thickness and/or surface topography. Another challenge in CMP processes is real time process control, whereby on-line, in real time CMP process parameters are adjusted in order to improve polish removal rate uniformity. Therefore, numerous improvements to CMP endpoint detection and CMP process control have been invented, as shown in the following patents.

U.S. Pat. No. 5,647,952 entitled “Chemical/Mechanical Polish (CMP) Endpoint Method” granted Jul. 15, 1997 to Lai-Juh Chen describes a method for endpoint detection in CMP in which infrared detection is used to measure the temperature of a selected polishing pad location which is abrading the surface of the semiconductor substrate. Endpoint is detected when a change in temperature of the rotating polishing pad occurs due to removal of a first material and contact by the rotating polishing pad to a second material.

U.S. Pat. No. 5,234,868 entitled “Method For Determining Planarization Endpoint During Chemical-Mechanical Polishing” granted Aug. 10, 1993 to William J. Cote describes a monitor structure surrounded by a moat. The moat causes polish removal to proceed faster at the monitor structure than at regions not surrounded by a moat. Polishing proceeds until the top of the monitor structure is exposed and results in a layer of planarized insulation above the metal pattern not surrounded by a moat. Visual inspection is employed to determine exposure of the top of the monitor structure. Alternately, monitoring is done electrically by detecting an electrical connection between the top of the metal monitor structure and the polishing pad.

U.S. Pat. No. 5,240,552 entitled “Chemcial-Mechanical Planarization (CMP) Of A Semiconductor Wafer Using Acoustical Waves For In-situ End Point Detection” granted Aug. 31, 1993 to Chris C. Yu et al. directs acoustical waves at the wafer during CMP and through analysis of the reflected wave form controls the planarization process.

U.S. Pat. No. 5,308,438 entitled “Endpoint Detection Apparatus and Method For Chemical/Mechanical Polishing” granted May 3, 1994 to William J. Cote et al. describes an endpoint detection method in which the power required to maintain a set rotational speed in a motor rotating the substrate is monitored. Endpoint is detectable because the power required to maintain a set rotational speed in a motor rotating the substrate significantly drops when the difficult to polish layer is removed.

U.S. Pat. No. 5,337,015 entitled “In-situ Endpoint Detection Method and Apparatus for Chemical-Mechanical Polishing Using Low Amplitude Input Voltage” granted Aug. 9, 1994 to Naftali E. Lustig et al. utilizes electrodes built into the polishing pad, and a high frequency, low voltage signal, and detection means as a method for measuring the thickness of a dielectric layer being polished.

U.S. Pat. No. 5,413,941 entitled “Optical End Point Detection Methods in Semiconductor Planarizing Polishing Processes” granted May 9, 1995 to Daniel A. Koos et al. describes a method for endpoint detection for polishing by impinging laser light onto the substrate being polished and measuring the reflected light. The intensity of the reflected light is a measure of the planarity of the polished surface.

U.S. Pat. No. 5,196,353 entitled “Method For Controlling a Semiconductor (CMP) Process By Measuring a Surface Temperature and Developing a Thermal Image of the Wafer” granted Mar. 23, 1993 to Gurtej S. Sandhu et al. describes the use of infrared radiation detection to measure the surface temperature of a semiconductor wafer during a polishing process. Sudden changes of temperature at the wafer surface during the polishing process can be used to detect an endpoint.

The present invention is directed to a novel and improved method for controlling a CMP (Chemical Mechanical Polishing) process in real time by measuring and mapping in two dimensions the surface temperature of the polishing pad during the CMP process. The method of the invention allows real time detection of CMP process endpoint and real time adjustment of CMP process parameters to improve the uniformity of removal of material from a semiconductor substrate during chemical mechanical polishing of the semiconductor substrate.

### SUMMARY OF THE INVENTION

It is a general object of the present invention to provide an improved method of monitoring and controlling CMP processes.

A more specific object of the present invention is to provide an improved method of monitoring and controlling CMP processes on-line, in real time, without necessity to interrupt the CMP process, unload the substrate for visual inspection or performance of specialized, time-consuming, and costly thickness and/or surface topography measurements.

A further object of the present invention is directed to an improved method for controlling a CMP (Chemical Mechanical Polishing) process in real time, which allows real time detection of CMP process endpoint and real time adjustment of CMP process parameters to improve the uniformity of removal of material from a semiconductor substrate during chemical mechanical polishing of the semiconductor substrate.

Another object of the present invention is to provide a new and improved process for CMP (Chemical Mechanical Polishing) in which the uniformity of the removal process is monitored, in-situ, by detecting the temperature of the polishing pad at a plurality of sites, mapping in two dimensions the thermal image of the polishing pad, and deriving the uniformity of the removal process from the temperature uniformity of the thermal image of the polishing pad.

And yet another object of the present invention is to provide an improved method of on-line endpoint detection for a CMP process, whereby a thermal imaging camera monitors a two dimensional area of the polishing pad on-line, during the polishing process. Two-dimensional maps of the temperature distribution on the polishing pad are stored versus polishing time, in computer memory, and detection of changes in the temperature maps is used to indicate polishing endpoint at an interface between layers deposited on the semiconductor substrate.

In accordance with the present invention, the above and other objectives are realized by using a method of controlling a CMP (Chemical Mechanical Polishing) process for a semiconductor substrate being polished by a rotating polishing pad, the method comprising the steps of: detecting and mapping in two dimensions the temperature of the rotating polishing pad during the CMP process; storing in computer memory the two dimensional map of the rotating polishing pad versus real polishing time; and controlling process parameters of the CMP process using the two dimensional temperature map of the rotating polishing pad temperature versus real polishing time, as stored in computer memory.

In a second embodiment of the present invention, the above and other objectives are realized by using a method of controlling the uniformity of removal of material in a CMP (Chemical Mechanical Polishing) process for a semiconductor substrate being polished by a rotating polishing pad, the method comprising: detecting and mapping in two dimensions the temperature of the rotating polishing pad during the CMP process; storing in computer memory the two dimensional temperature map of the rotating polishing pad temperature versus real polishing time; and adjusting polishing process parameters of the CMP process to maximize the uniformity of the two dimensional temperature maps of the rotating polishing pad temperature versus real polishing time.

In a third embodiment of the present invention, the above and other objectives are realized by using a method of detecting endpoint for removal of material in a CMP (Chemical Mechanical Polishing) process for a semiconductor substrate being polished by a rotating polishing pad, the method comprising: detecting and mapping in two dimensions the temperature of the rotating polishing pad during the CMP process; storing in computer memory the two dimensional temperature map of the rotating polishing pad temperature versus real polishing time; and detecting endpoint for removal of material when the temperature of the polishing pad changes.

### BRIEF DESCRIPTION OF THE DRAWINGS

The object and other advantages of this invention are best described in the preferred embodiments with reference to the attached drawings that include:

FIG. 1A, which schematically, in cross-sectional representation illustrates a polishing apparatus, used in accordance with the method of the invention.

FIG. 1B, which is a top view of the apparatus illustrated in FIG. 1A.

FIG. 2, which plots polishing pad temperature versus polishing pad radius.

FIG. 3A, which plots polishing pad temperature versus polishing pad radius at different polish times.

FIG. 3B, which depicts the materials being polished at the different polish times illustrated in FIG. 3A.

FIG. 4, which plots polish pad temperature uniformity versus polish removal uniformity.

FIG. 5, which plots polishing pad temperature uniformity and polish removal uniformity verus number of substrates processed on a CMP polishing pad.

FIG. 6 is a flow chart of the method of the preferred embodiment of the present invention.

### DESCRIPTION OF THE PREFERRED EMBODIMENTS

The improved method of controlling a CMP (Chemical Mechanical Polishing) process for a semiconductor substrate being polished by a rotating polishing pad will now described in detail.

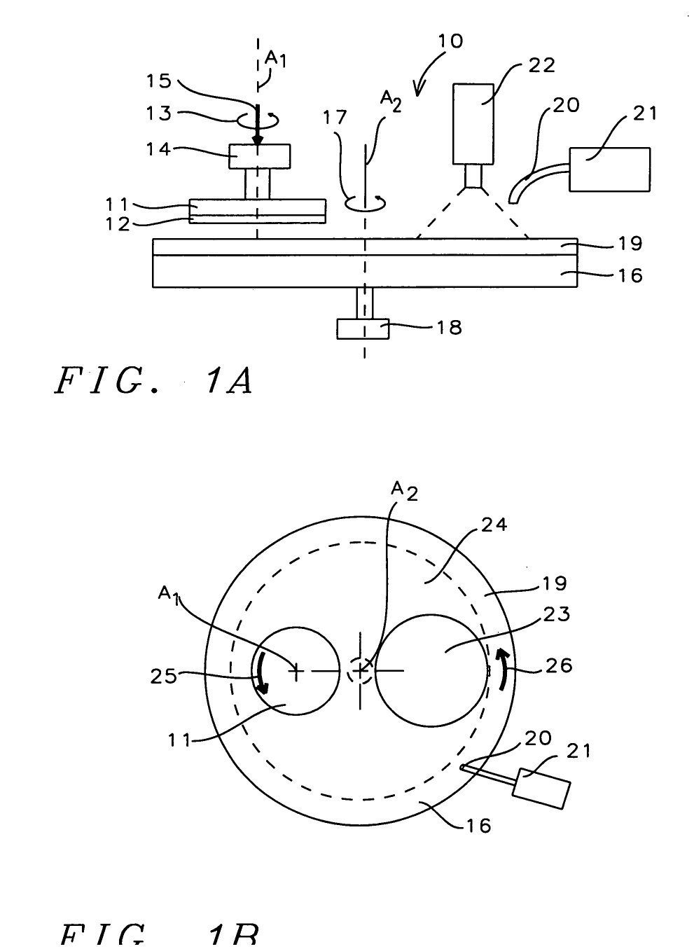

FIGS. 1A and 1B are schematic views of a CMP (Chemical Mechanical Polishing) apparatus for use in accordance with the method of the invention. In FIG. 1A, the CMP apparatus, generally designated as 10, is shown schematically in cross-sectional representation. The CMP apparatus 10 includes a substrate carrier 11 for holding a semiconductor substrate 12. The substrate carrier 11 is mounted for continuous rotation about axis A₁ in a direction indicated by arrow 13 by drive motor 14. The substrate carrier 11 is adapted so that a force indicated by arrow 15 is exerted on semi-conductor substrate 12. The CMP apparatus 10, also, includes a polishing platen 16 mounted for continuous rotation about axis A₂ in a direction indicated by arrow 17 by drive motor 18. A polishing pad 19 formed of a material such as blown polyurethane is mounted to the polishing platen. A polishing slurry containing an abrasive fluid, such as silica or alumina abrasive particles suspended in either a basic or an acidic solution, is dispensed onto the polishing pad 19 through a conduit 20 from a temperature controlled reservoir 21. An infrared detection device 22, comprising a thermal imaging camera, is mounted so as to detect infrared radiation from a two dimensional area 23 on the polishing pad 19, as shown in FIG. 1B. The two dimensional area 23 traces as annular ring 24 on the polishing pad 19, as shown in FIG. 1B, due to the continuous rotation of the polishing pad 19. The size and location of area 23 are selected so as to produce a thermal image of regions of the rotating polishing pad which are not in contact with the semiconductor substrate during the CMP process and regions of the rotating polishing pad which are abrading the semiconductor substrate during the CMP process. Area 23 should cover an area larger than the size of the substrate being polished. For example, when polishing a semiconductor substrate having a substrate diameter of about 10 cm, area 23 has a diameter of larger than 10 cm. In general, the CMP apparatus illustrated in FIGS. 1A and 1B is well known in the art. One such apparatus is manufactured by IPEC Westech Systems, Inc. and designated as a Model 372M Polisher. A suitable thermal image camera 22 is, for example, an Inframetrics ThermaCAM® SC1000 Camera, an AGEMA Thermovision® 550 Camera, or an AGEMA Thermovision® 570 Basic I Camera.

In FIG. 1B, which is a schematic top view of the CMP apparatus 10, shown in FIG. 1A, the key elements are shown. Substrate carrier 11 is shown to rotate in a direction indicated by arrow 25 about an axis A₁. Polishing platen 16 is shown to rotate in a direction indicated by arrow 26 about an axis A₂. The polishing slurry is dispensed onto the polishing pad 19 through conduit 20 from a temperature controlled reservoir 21. Infrared radiation is detected from a two dimensional area 23 on the polishing pad 19.

In U.S. Pat. No. 5,647,952 entitled “Chemical/Mechanical Polish (CMP) Endpoint Method” granted Jul. 15, 1997 to Lai-juh Chen a method is described for endpoint detection in CMP in which infrared detection at a single point on a rotating polishing pad is used to measure the temperature of the annular ring traced by the single point. The single point is located on a region of the polishing pad that is abrading the surface of the semiconductor substrate. This method is satisfactory for endpoint detection in which either an increase in temperature or a decrease in temperature of the polishing pad indicates a change of material being polished by the rotating polishing pad. However, the method described in U.S. Pat. No. 5,647,952 does not allow measurement of polish material removal uniformity, since the detected temperature data are obtained from a small, limited region of the rotating polishing pad.

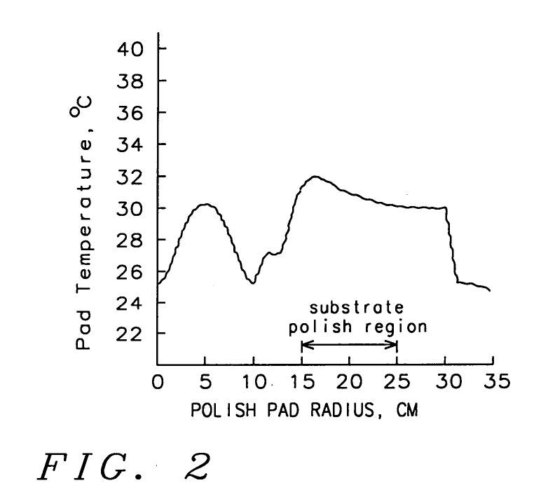

By using a thermal imaging camera to detect a two dimensional thermal image of a portion of the rotating polishing pad the relationship of process parameters to polishing pad temperature and, more importantly, of process parameters to polishing pad temperature uniformity are derived. The infrared camera records the temperature of the whole working area of the rotating polishing pad during the polishing operation. The thermal image covers the region from the center of the polishing pad to the edge of the polishing pad. The temperature controlled polishing slurry is dispensed onto the center area of the rotating polishing pad. The pad center region (including the slurry injection area) is cooler than the polish area. Also, the concentric circle of the pad edge is cool, because this portion of the polishing pad is not abrading the semiconductor substrate. FIG. 2 shows the distribution of polishing pad temperature along a radius of the rotating polishing pad. The temperature is low at the center (radius=0) of the polishing pad, increases in the region of the polishing pad that is abrading the surface of the semiconductor substrate, and is low again at the edge (radius=30 cm) of the polishing pad.

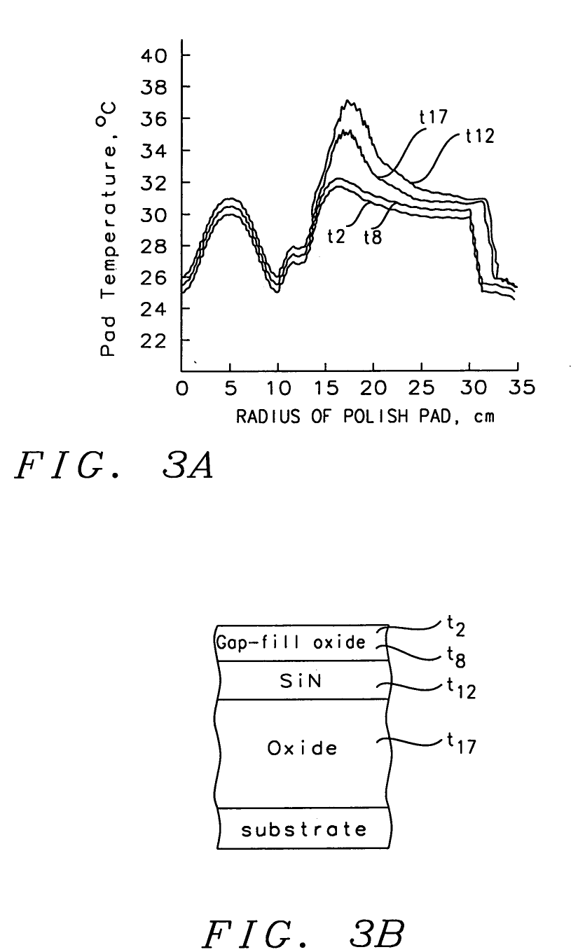

FIG. 3A shows the change in distribution of polishing pad temperature along a radius of the rotating polishing pad as a function of the polishing times, t₂, t₈, t₁₂ and t₁₇. In this case, as illustrated in FIG. 3B, the polishing is proceeding first on a gap-fill oxide layer (times t₂ and t₈), then on a silicon nitride layer (time t₁₂), and finally on a second oxide layer (time t₁₇). The temperature line scans, shown in FIG. 3A, at times t₂ and t₈ show the temperature distribution on the rotating polishing pad while polishing gap-fill oxide. Upon removal of the gap-fill oxide the polishing proceeds into silicon nitride, which is a hard, difficult to polish material. This causes an increase in the temperature of the rotating polishing pad as shown for the temperature line scan taken at time t₁₂. Further polishing removes the silicon nitride layer and polishing continues on the underlying oxide layer, which is a soft, easy to polish material. Thus a decrease in rotating polishing pad temperature is observed at time t₁₇.

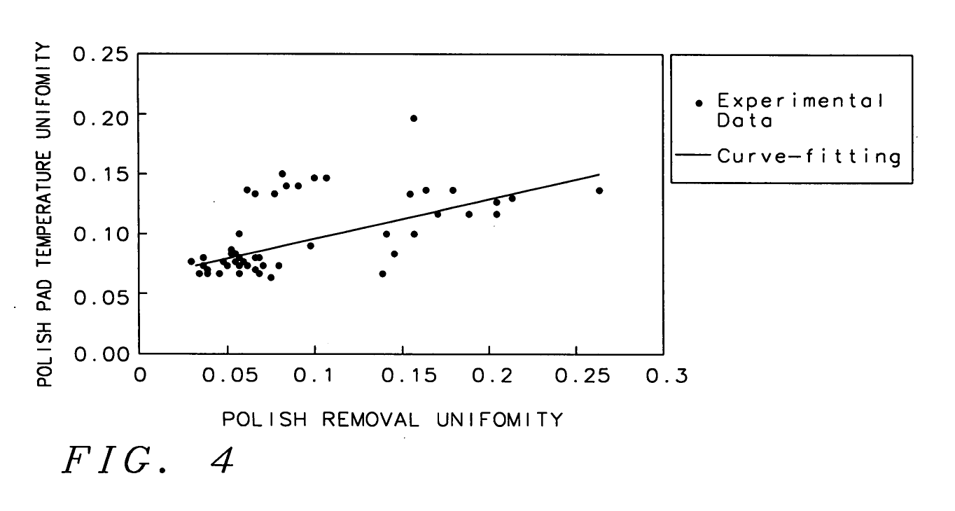

FIG. 3A shows that there is a non-uniform distribution of temperature along the radius of the rotating polishing pad during CMP. Further studies show that the degree of polishing pad temperature uniformity can be correlated to the degree of polishing uniformity on the semiconductor substrate. FIG. 4 shows a linear relationship between polishing pad temperature uniformity and the uniformity of material removed from the semiconductor substrate. Therefore, the two dimensional thermal image of the rotating polishing pad can be used to indicate the polish removal uniformity on the semiconductor substrate.

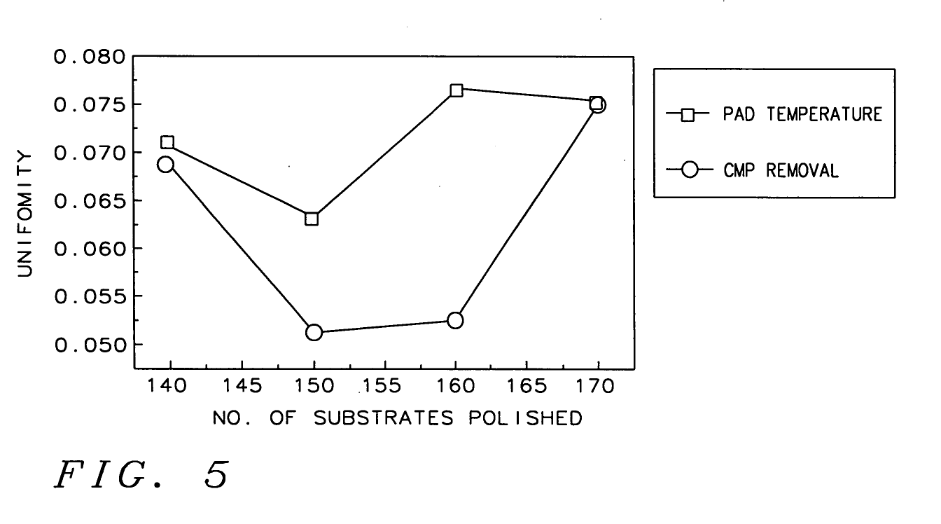

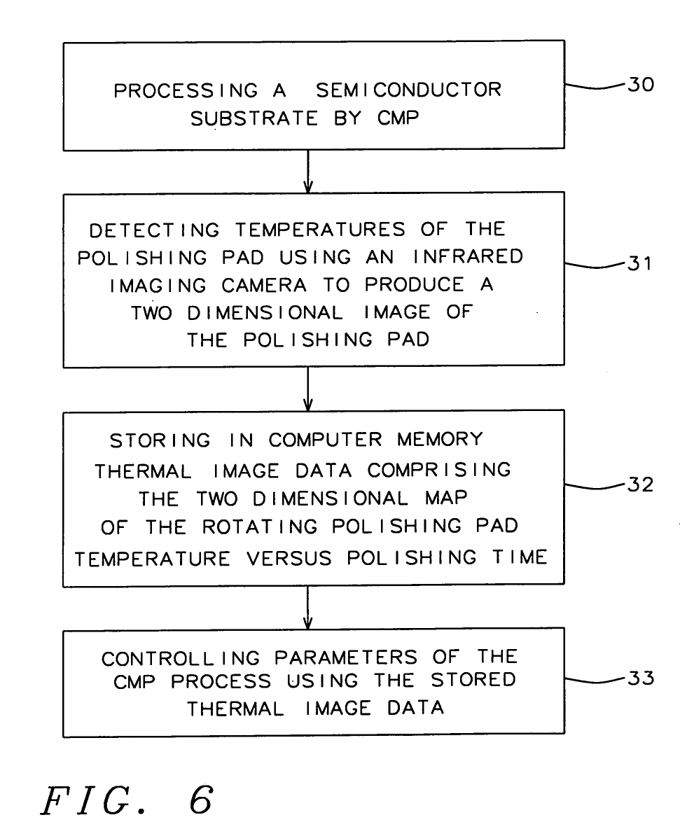

Another issue for CMP manufacturing is the relative short lifetime for polishing pads. A typical polishing pad lifetime allows processing of about 300 to 600 substrates. The polishing pad lifetime depends on a number of factors, e.g. polishing slurry properties, pad conditioning material, CMP process parameters and polished layer characteristics. In order to prolong polishing pad lifetime and to reduce manufacturing cost one needs to monitor the functioning of the polishing pad over its lifetime. However, to date there has not existed a useful pad monitoring scheme which does not require interruption of the CMP process and CMP equipment downtime. FIG. 5 shows that there is a similar relationship between the uniformity of temperature on the rotating polishing pad and the uniformity of material removed from the substrate during polishing over the lifetime of the polishing pad, as represented by the number of substrates processed. In the example shown in FIG. 5, a CMP removal uniformity of greater than about 6% indicates that the polishing pad has reached end-of-life. Also, the wide variations in removal uniformity indicate end-of-life for the polishing pad. A similar degree of polishing pad temperature uniformity is observed and variations in polishing pad temperature uniformity correspond to the measured CMP removal uniformity. Therefore, by monitoring the temperature of the polishing pad, mapping in two dimensions the temperature of the rotating polishing pad during the CMP process, calculating the uniformity of the temperature of the rotating polishing pad during CMP, storing these data in computer memory and then comparing these data one can predict the end-of-life for a polishing pad. Such pad temperature uniformity trend charts allow maximum utilization of a polishing pad before degradation of product yield by using a polishing pad beyond its useful lifetime. FIG. 6 is a flow chart for controlling a CMP process in accordance with the method of the invention. In step 30 a semiconductor substrate is processed by CMP. During the CMP process an infrared imaging camera produces a two dimensional image of the rotating polishing pad, step 31. Two dimensional images of the rotating polishing pad versus polishing time are stored in computer memory, step 32. Then the two dimensional thermal image data are used to control parameters of the CMP process, step 33.

While the invention has been particularly shown and described with reference to the preferred embodiments thereof, it will be understood by those skilled in the art that various changes in form and details may be made without departing from the spirit and scope of the invention.

1. A method of controlling a CMP (Chemical Mechanical Polishing) process for a semiconductor substrate being polished by a rotating polishing pad, the method comprising:
detecting and mapping in two dimensions the temperature of the rotating polishing pad during the CMP process;
storing in computer memory the two dimensional temperature map of the rotating polishing pad temperature versus real polishing time; and
controlling process parameters of the CMP process using the two dimensional temperature maps of the rotating polishing pad temperature versus real polishing time, as stored in computer memory.

2. The method of claim 1, wherein the temperature of the rotating polishing pad is detected with an infrared camera.

3. The method of claim 2, wherein said infrared camera records a two dimensional thermal image of a portion of the rotating polishing pad.

4. The method of claim 1, wherein the mapping in two dimensions of the rotating polishing pad temperature includes regions of the rotating polishing pad which are not in contact with the semiconductor substrate during the CMP process and regions of the rotating polishing pad which are abrading the semi-conductor substrate during the CMP process.

5. The method of claim 1, wherein the uniformity of removal of material by the CMP process is controlled by detecting the uniformity of the polishing pad temperature and adjusting polishing process parameters to improve the uniformity of the polishing pad temperature during the polishing process.

6. The method of claim 1, wherein endpoint for removal of a material is established by detecting a change of temperature of the polishing pad versus polishing time.

7. A method of controlling the uniformity of removal of material in a CMP (Chemical Mechanical Polishing) process for a semiconductor substrate being polished by a rotating polishing pad, the method comprising:
detecting and mapping in two dimensions the temperature of the rotating polishing pad during the CMP process;
storing in computer memory the two dimensional temperature map of the rotating polishing pad temperature versus real polishing time; and
adjusting polishing process parameters of the CMP process to maximize the uniformity of the two dimensional temperature maps of the rotating polishing pad temperature versus real polishing time.

8. The method of claim 7, wherein the temperature of the rotating polishing pad is detected with an infrared camera.

9. The method of claim 8, wherein said infrared camera records a two dimensional thermal image of a portion of the rotating polishing pad.

10. The method of claim 7, wherein the mapping in two dimensions of the rotating polishing pad temperatures includes regions of the rotating polishing pad which are not in contact with the semiconductor substrate during the CMP process and regions of the rotating polishing pad which are abrading the semi-conductor substrate during the CMP process.

11. A method of detecting endpoint for removal of material in a CMP (Chemical Mechanical Polishing) process for a semiconductor substrate being polished by a rotating polishing pad, the method comprising:
detecting and mapping in two dimensions the temperature of the rotating polishing pad during the CMP process;
storing in computer memory the two dimensional temperature map of the rotating polishing pad temperature versus real polishing time; and
detecting endpoint for removal of material when the temperature of the polishing pad changes.

12. The method of claim 11, wherein the temperature of the rotating polishing pad is detected with an infrared camera.

13. The method of claim 12, wherein said infrared camera records a two dimensional thermal image of a portion of the rotating polishing pad.

14. The method of claim 11, wherein the mapping in two dimensions of the rotating polishing pad temperatures includes regions of the rotating polishing pad which are not in contact with the semiconductor substrate during the CMP process and regions of the rotating polishing pad which are abrading the semi-conductor substrate during the CMP process.

15. The method of claim 11, wherein the temperature of the rotating polishing pad decreases due to removal of a hard, difficult to polish material followed by contact of the rotating polishing pad with a soft, easy to polish material.

16. The method of claim 11, wherein the temperature of the rotating polishing pad increases due to removal of a soft, easy to polish material followed by contact of the rotating polishing pad with a hard, difficult to polish material.
